(19) United States
(12) Patent Application Publication
(10) Pub. No.: US 2015/0022975 A1
(43) Pub. Date: Jan. 22, 2015

(54) METHOD AND SYSTEM FOR AN IMMERSION BOILING HEAT SINK

(71) Applicant: General Electric Company, Schenectady, NY (US)

(72) Inventors: Eric Ayres Browne, Latham, NY (US); Satish Sivarama Gunturi, Albany, NY (US); Brian Magann Rush, Niskayuna, NY (US); Rixin Lai, Clifton Park, NY (US); Anurag Kasyap Vejjupalle Subramanyam, Latham, NY (US)

(73) Assignee: General Electric Company, Schenectady, NY (US)

(21) Appl. No.: 13/946,408

(22) Filed: Jul. 19, 2013

(51) Int. Cl. H05K 7/20

(52) U.S. Cl. CPC H05K 7/20309
USPC 361/700

(57) ABSTRACT

A method and system for cooling a heat-generating component are provided. The system includes a heat generating electronic component including a heat conductive face, a heat sink device including at least one open face pin fin array surface directly coupled to the conductive face, each fin including a distal end including an outwardly facing contact area, the contact areas covering only a portion of the conductive face, the contact areas configured to carry electrical current therethrough, and an immersion of dielectric fluid contained in a vessel, the vessel including a heat-conductive hull at least partially submerged in a heat sink fluid.

### STATEMENT REGARDING FEDERALLY SPONSORED RESEARCH AND DEVELOPMENT

The U.S. Government has certain rights in this invention as provided for by the terms of Contract No. DE-AC26-07NT42677.

### BACKGROUND OF THE DISCLOSURE

This description relates to power electronics, and, more particularly, to a method and systems for operating power electronics in harsh environments.

Deep sea oil and gas exploration and production will require large scale subsea factories. These factories will require power on the ten's of megawatt scale. This power will require processing at the sea floor in deep sea conditions and the electronics supplying and controlling the power will need to be essentially maintenance-free for extended periods of time. One source of frequent maintenance is cooling the power electronics using a deionizing water system.

Pool type cooling of power electronics has been attempted, however due to the heat sink design used, the heat transfer performance has been problematic.

### BRIEF DESCRIPTION OF THE INVENTION

In one embodiment, an electronic component cooling system includes a heat generating electronic component including a heat conductive face, a heat sink device including at least one open face pin fin array surface directly coupled to the conductive face, each fin including a distal end including an outwardly facing contact area, the contact areas covering only a portion of the conductive face, the contact areas configured to carry electrical current therethrough, and an immersion of dielectric fluid contained in a vessel, the vessel including a heat-conductive hull at least partially submerged in a heat sink fluid, where heat generated in the electronic component is transferred through the face into the dielectric fluid and the fins of the heat sink device and into the dielectric fluid to generate boiling of the dielectric fluid, at least a portion of the dielectric fluid vapor from boiling transfers heat to the bulk dielectric fluid and returns to a liquid state, a second portion of the dielectric fluid vapor escapes the bulk dielectric fluid and condenses on an inner surface of the vessel.

In another embodiment, a method of cooling a heat-generating component includes providing a heat sink device that includes a first face and an opposing second face, at least one of the first face and the second face including a plurality of fins spaced-apart by channels therebetween and extending outwardly from the heat sink device, each fin including an outwardly facing contact area. The method also includes positioning the plurality of contact areas in direct contact with a surface of the heat-generating component, a first portion of the surface being covered by the plurality of contact areas, a second portion of the surface being exposed, immersing the heat sink device and the heat-generating component in a dielectric cooling fluid, conducting heat from the surface of the heat-generating component through the plurality of contact areas into the heat sink device, and maintaining conditions of the fluid such that boiling of at least a portion the fluid occurs at least one of at the second portion and at a surface of any of the fins.

In yet another embodiment, a subsea power electronic device includes a pressure vessel configured to withstand sea pressure at a predetermined operating depth with an approximately one atmosphere internal pressure, a plurality of power electronic devices positioned within the pressure vessel, the plurality of power electronic devices alternately stacked with one or more heat sink devices clamped therebetween, the heat sink devices coupled in heat transfer communication with the power electronic devices, the heat sink devices coupled in electrical conduction with adjacent power electronic devices, the heat sink devices including a plurality of crisscrossed channels in at least one face of the heat sink device, and a quantity of dielectric fluid sufficient to partially fill the pressure vessel and to submerge the stack of power electronic devices and heat sink devices, where heat generated in the plurality of power electronic devices is transferred to the quantity of dielectric fluid directly and through the one or more heat sink devices, a portion of the dielectric fluid changes to vapor phase due to boiling and a portion of the dielectric fluid remains in liquid phase, the heat in the dielectric fluid is advected to the vessel where the heat is transferred to the sea through he vessel.

### BRIEF DESCRIPTION OF THE DRAWINGS

FIGS. 1-4 show exemplary embodiments of the method and apparatus described herein.

FIG. 1 is a side elevation diagram of a pool-cooling pressure vessel in accordance with an example embodiment of the present disclosure.

FIG. 2 is an enlarged side elevation diagram of the power electronics assembly (shown in FIG. 1.)

FIG. 3 is a perspective view of an open face pin fin array heat sink in accordance with an example embodiment of the present disclosure.

FIG. 4 is a perspective view of a heat sink in accordance with another example embodiment of the present disclosure.

Although specific features of various embodiments may be shown in some drawings and not in others, this is for convenience only. Any feature of any drawing may be referenced and/or claimed in combination with any feature of any other drawing.

Unless otherwise indicated, the drawings provided herein are meant to illustrate features of embodiments of the disclosure. These features are believed to be applicable in a wide variety of systems comprising one or more embodiments of the disclosure. As such, the drawings are not meant to include all conventional features known by those of ordinary skill in the art to be required for the practice of the embodiments disclosed herein.

### DETAILED DESCRIPTION OF THE INVENTION

The following detailed description illustrates embodiments of the invention by way of example and not by way of limitation. It is contemplated that the invention has general application to cooling heat-generating devices in industrial, commercial, and residential applications.

Described herein is a novel heat sink design used in an assembly called a press-pack stack of power electronics. The heat sink provides superior thermal performance to allow for passive immersion cooling of the press-pack stack electronics. This approach replaces pumped loops using deionized water. The heat sink replaces existing heat sinks that require deionized water at high flow rates with a heat sink that is immersed in a dielectric fluid.

Thermal waste energy in the form of heat conducts out of a press-pack style part and into the heat sink. This is true in typical use as well and is how the device packaging was designed. The heat conducts mainly across the two pole faces. These are circular flat faces on opposite sides of a short and wide cylinder (like a hockey puck). These pole faces are primarily used to conduct current but are also used as the heat exit path. Therefore, the heat sink that is in contact with these faces must conduct electricity and dissipate the waste heat. Previous designs used internal flows of water within these heat sinks to remove heat from the electrical components. For deep sea power converters and other potential applications where serviceability is limited and long lifetime is required, the pump and deionizing system can be eliminated through the use of a pool boiling immersion thermal management approach. The presently claimed heat sink is the first pool boiling heat sink for press-pack parts. The surrounding fluid is turned into vapor by the addition of the waste heat. That vapor then rises due to buoyancy forces. The design of the heat sink is non-trivial as area should be maximized for bubble nucleation sites but surface superheat must be maintained for nucleation. Additionally, the vapor must have an unobstructed path to depart such that it does not impede, or does so to a minimized extent, continued bubble nucleation. The heat is then advected by the motion of the bubble which has a specific energy higher than that of the surrounding liquid due to its vapor state. In this way, all of the waste heat can be removed from the press-pack stack removing the requirement for electrically isolated but conducting, water-cooled heat sinks.

By eliminating the unreliable cooling systems typically used in land based systems that also require regular maintenance, the packaging of a motor drive system into a pressure vessel for use in deep sea applications is possible.

The following description refers to the accompanying drawings, in which, in the absence of a contrary representation, the same numbers in different drawings represent similar elements.

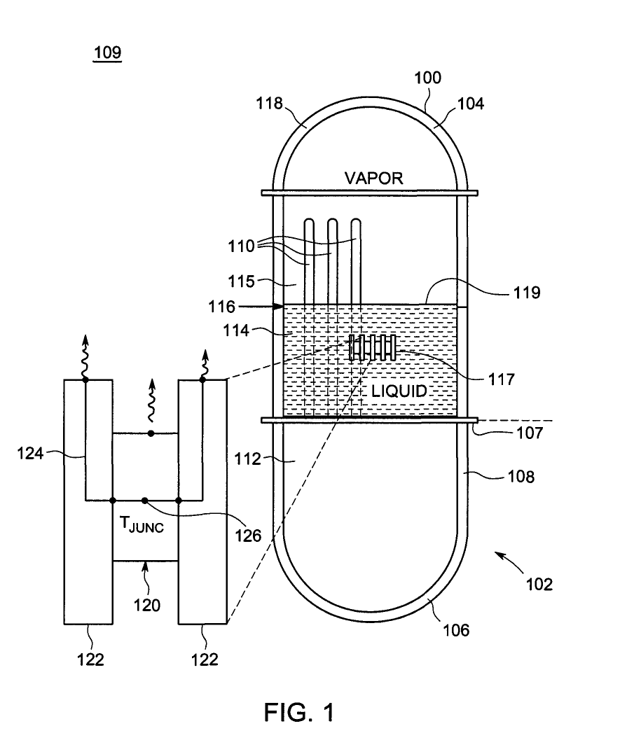

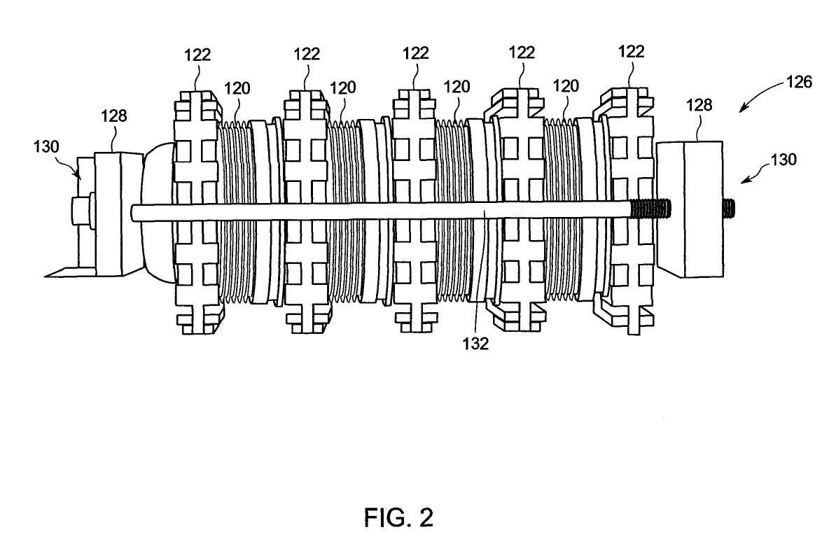

FIG. 1 is a side elevation diagram of a pool-cooling pressure vessel 100 in accordance with an example embodiment of the present disclosure. Pressure vessel 100 includes a hull 102 having, in the example embodiment, a first hemispherical head 104, a second hemispherical head 106, and a cylindrical body 108 extending therebetween. Cylindrical body 108 includes a pressure barrier 107 that divides vessel 100 into an upper portion and a lower portion. Cylindrical body 108 includes a plurality of radially inwardly extending stiffening ribs 110 that are ribs configured to increase a surface area of an interior surface 112 of hull 102. In the example embodiment, pressure vessel 100 includes a first volume 114 of dielectric liquid and a remainder of the volume of pressure vessel 100 is a second volume 115 of dielectric vapor. First volume 114 and second volume 115 are contained in the upper portion of cylindrical body 108. Conditions in the upper portion of pressure vessel 100 are maintained so that the dielectric liquid and dielectric vapor are near equilibrium in an approximately saturated state. Portions of the dielectric liquid and dielectric vapor may at various times or conditions may be in an other than saturated state, for example, sub-cooled. A pressure in the lower portion of cylindrical body 108 is at approximately ambient sea pressure. A level 116 of dielectric liquid in pressure vessel 100 is maintained at a level sufficient to fully submerge one or more power electronics assemblies 117. In various embodiments, power electronics assemblies 117 are submerged in a dielectric liquid and contained inside cylindrical pressure vessel 100 oriented vertically with respect to gravity. Second volume 115 provides a condensation area where the dielectric vapor is in contact with a wall 118 of pressure vessel 100. Most of the heat generated in power electronics assemblies 117 passes through a packaging portion (shown in FIG. 2) and into the dielectric vapor via boiling. The boiled vapor rises through the dielectric liquid to a free surface 119. Second volume 115 is bounded by a warm pool of dielectric liquid from which dielectric vapor is entering, and cold wall 118 where the heat contained in the dielectric vapor is removed through condensation. The latent heat of the dielectric vapor is rejected into wall 118. The heat then conducts through the vessel wall 110 and into an external heat sink 109, such as, but, not limited to the ocean or other volume of fluid that acts as a heat sink by convection. In one aspect pressure vessel 100 behaves as a thermosyphon system with distributed heat loads. This heat removal pathway is thermally driven and represents an effective non-pumped transport of thermal energy.

In various embodiments, the dielectric liquid has a boiling point of approximately 35° C. at approximately one atmosphere so that the saturation temperature Tₛₐₜ falls between sea temperature Tₛₑₐ and desired temperature of power electronics assemblies 108. One example of a dielectric liquid is Novec 7000™ manufactured by 3M Company, St. Paul, Minn.

In addition to providing electrical isolation and eliminating a circulating pump, pool boiling inherently tends toward better temperature uniformity because of an increase in boiling effectiveness with increasing surface temperature. A limit to this trend of improving performance with additional heat is referred to as the critical heat flux and components of pressure vessel 100 are sized and operate to avoid the critical heat flux.

A single power semiconductor device 120 may be packaged with other devices 120 to form power electronics assemblies 117. One type of packaging includes a plurality of power semiconductor devices 120 provided in a press-pack form where silicon wafers or discs are joined in electrical series in a hockey-puck like ceramic housing, such as an Integrated Gate Commutated Thyristor (IGCT), Insulated Gate Bipolar Transistor (IGBT), Injection-Enhanced Gate Transistor (IEGT), Thyristor (ETT or LTT), and diodes in press-pack package. Each power semiconductor device 120 is sandwiched between two heat sinks 122, which form a portion of the electrical series path through power electronics assemblies 117 and a portion of the heat transfer path through power electronics assemblies 117. A heat flow path 124 illustrates schematically a path heat generated in power semiconductor device 120 dissipates from a junction 126 of power semiconductor device 120.

Heat generated in each junction 126 first moves into adjacent heat sinks through conduction. Two heat transfer paths 124 are available from the submerged press-pack heat sinks 122 to the pressure vessel inner wall 118 through the vapor phase (via boiling and then condensation) and/or to the pressure vessel inner wall 110 through the liquid phase (via convection/conduction). The amount of heat transferred through either path is dependent on the relative thermal resistance for each path. The heat then conducts through the pressure vessel wall 118 and finally into the seawater ultimate heat sink 109 through convection.

FIG. 2 is an enlarged side elevation diagram of power electronics assembly 108. In the example embodiment, power electronics assembly 108 includes a stack of four power semiconductor devices 120 and five heat sinks 122 sandwiched together in a clamping device 126 that includes a strongback 128 at each end 130 coupled together through one or more threaded rods 132.

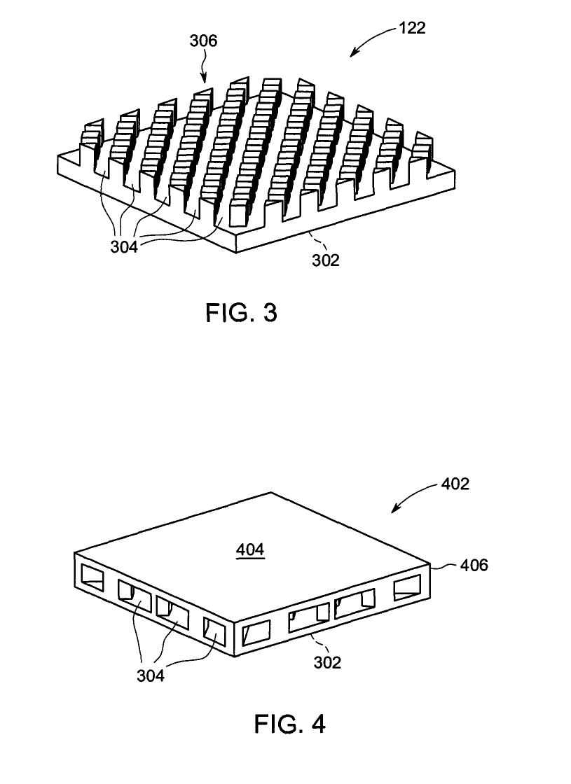

FIG. 3 is a perspective view of an open face pin fin array heat sink 122 in accordance with an example embodiment of the present disclosure. In the example embodiment, heat sink 122 includes a planar face 302. Heat sink 122 also includes a plurality of channels 304 formed in a boiling transfer face 306 opposing planar face 302 and configured to abut an adjacent power semiconductor device power semiconductor device 120. In the example embodiment, channels 304 are crisscrossing rectangular channels set 45° from vertical rather than directly vertical. This shape permits greater vapor area and the sharing of that vapor to additional areas rather than forcing it to flow in the channel in which it was created.

FIG. 4 is a perspective view of a heat sink 402 in accordance with another example embodiment of the present disclosure. In this embodiment, heat sink 122 includes planar face 302, the plurality of channels 304 and a second planar face 404. Heat sink 122 maybe formed using two heat sinks 122 face-to-face or by applying a flat plate 406 over boiling transfer face 306. In the example embodiment, channels 304 are crisscrossing rectangular channels set 45° from vertical rather than directly vertical. As described above, this configuration permits greater vapor area and the sharing of that vapor to additional areas rather than forcing it to flow in the channel in which it was created. This configuration is helpful because the pole face of power semiconductor device 120 is circular and the straight channels 304 of heat sinks 122 are all of equal length.

Channels 304 in both heat sinks 122 and 402 also increase a surface area of boiling transfer face 306 to improve boiling of dielectric liquid on boiling transfer face 306.

It will be appreciated that the above embodiments that have been described in particular detail are merely example or possible embodiments, and that there are many other combinations, additions, or alternatives that may be included.

While the disclosure has been described in terms of various specific embodiments, it will be recognized that the disclosure can be practiced with modification within the spirit and scope of the claims.

The above-described embodiments of a method and system of heat transfer using multiphase pool boiling provides a cost-effective and reliable means for cooling power electronics where thermal performance, electrical isolation and the absence of both a pump and regular maintenance are all achieved with the pool boiling concept. More specifically, the method and system described herein facilitate removing heat by boiling and aiding coolant using a buoyancy of the vapor bubbles and configuration of cooling channels in a heat sink device. As a result, the method and systems described herein facilitate autonomous mechanically unaided cooling of power electronics in a cost-effective and reliable manner.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. An electronic component cooling system comprising:
a heat generating electronic component comprising a heat conductive face;
a heat sink device including at least one open face pin fin array surface directly coupled to said conductive face, each fin including a distal end comprising an outwardly facing contact area, the contact areas covering only a portion of said conductive face, said contact areas configured to carry electrical current therethrough; and
an immersion of dielectric fluid contained in a vessel, the vessel comprising a heat-conductive hull at least partially submerged in a heat sink fluid,
where heat generated in the electronic component is transferred through the face into the dielectric fluid and the fins of the heat sink device and into the dielectric fluid to generate boiling of the dielectric fluid, at least a portion of the dielectric fluid vapor from boiling transfers heat to the bulk dielectric fluid and returns to a liquid state, a second portion of the dielectric fluid vapor escapes the bulk dielectric fluid and condenses on an inner surface of the vessel.

2. The system of claim 1, further comprising an electronic component assembly comprising one or more electronic components and one or more heat sink devices clamped together in a press-pack stack configuration.

3. The system of claim 1, wherein said hull comprises a first hemispherical head, a second hemispherical head, and a cylindrical body extending therebetween, the cylindrical body comprising a plurality of radially inwardly extending stiffening ribs, said ribs configured to increase a surface area of an interior surface of said hull.

4. The system of claim 1, wherein said hull is configured to maintain a pressure of less than ten atmospheres within the vessel.

5. The system of claim 1, wherein said vessel is configured to operate with a pressure differential of greater than one hundred pounds per square inch (psi) across the hull.

6. The system of claim 1, wherein the dielectric fluid comprises a boiling point of approximately 35° Celsius at one atmosphere of pressure.

7. The system of claim 1, wherein the immersion of dielectric fluid comprises a closed fluid system where all the dielectric fluid remains in the vessel during electronic component cooling.

8. A method of cooling a heat-generating component, the method comprising:
providing a heat sink device that includes a first face and an opposing second face, at least one of the first face and the second face including a plurality of fins spaced-apart by channels therebetween and extending outwardly from the heat sink device, each fin including an outwardly facing contact area;
positioning the plurality of contact areas in direct contact with a surface of the heat-generating component, a first portion of the surface being covered by the plurality of contact areas, a second portion of the surface being exposed;
immersing the heat sink device and the heat-generating component in a dielectric cooling fluid;
conducting heat from the surface of the heat-generating component through the plurality of contact areas into the heat sink device; and
maintaining conditions of the fluid such that boiling of at least a portion the fluid occurs at at least one of the second portion and a surface of any of the fins.

9. The method of claim 8, wherein providing a heat sink device comprises providing a heat sink device that includes a plurality of fins spaced-apart by channels therebetween and extending outwardly from the heat sink device on each of the first face and the second face.

10. The method of claim 8, wherein providing a heat sink device comprises providing a first heat sink that includes a plurality of fins spaced-apart by channels therebetween and extending outwardly from the heat sink on one of the first face and the second face and a flat planar surface on the other one of the first face and the second face.

11. The method of claim 10, further comprising:
providing a second heat sink that includes a plurality of fins spaced-apart by channels therebetween and extending outwardly from the heat sink on one of the first face and the second face and a flat planar surface on the other one of the first face and the second face; and
directly coupling the flat planar surfaces of the first and second heat sinks in thermal contact.

12. The method of claim 11, further comprising conducting electrical current through the first heat sink to the second heat sink.

13. The method of claim 8, further comprising conducting electrical current through the heat sink device.

14. The method of claim 8, further comprising sandwiching the heat sink device in electrical series between two power electronics devices.

15. The method of claim 8, wherein providing a heat sink device comprise providing the heat sink device having the plurality of contact surfaces in the same plane.

16. The method of claim 8, further comprising directing vapor generated by the boiling from the heat sink device through the channels using a buoyancy of the vapor in the fluid.

17. A subsea power electronic device comprising:
a pressure vessel configured to withstand sea pressure at a predetermined operating depth with an approximately one atmosphere internal pressure;
a plurality of power electronic devices positioned within the pressure vessel, the plurality of power electronic devices alternately stacked with one or more heat sink devices clamped therebetween, the heat sink devices coupled in heat transfer communication with the power electronic devices, the heat sink devices coupled in electrical conduction with adjacent power electronic devices, the heat sink devices comprising a plurality of criss-crossed channels in at least one face of the heat sink device, and
a quantity of dielectric fluid sufficient to partially fill the pressure vessel and to submerge the stack of power electronic devices and heat sink devices, where
heat generated in said plurality of power electronic devices is transferred to the quantity of dielectric fluid directly and through said one or more heat sink devices, a portion of the dielectric fluid changes to vapor phase due to boiling and a portion of the dielectric fluid remains in liquid phase, the heat in the dielectric fluid is advected to the vessel where the heat is transferred to the sea through he vessel.

18. The device of claim 17, wherein the quantity of dielectric fluid is maintained at saturation conditions within the vessel.

19. The device of claim 17, wherein said heat sink devices each comprise a plurality of channels formed in at least one face of the heat sink devices, the channels arranged in a grid configuration intersecting at a predetermined angle.

20. The device of claim 19, wherein at least some of the channels are non-vertical during operation.
